(19) United States
(12) Patent Application Publication
(10) Pub. No.: US 2007/0042541 A1
(43) Pub. Date: Feb. 22, 2007

(54) Semiconductor device and its manufacture method

(75) Inventor: Kazutoshi Izumi, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/589,085

(22) Filed: Oct. 30, 2006

Related U.S. Application Data
(63) Continuation of application No. PCT/JP04/10646, filed on Jul. 27, 2004.

(51) Int. Cl. H01L 21/8244

(52) U.S. Cl. 438/238

(57) ABSTRACT

A method for manufacturing a semiconductor device by which deterioration in the characteristics of an oxide dielectric capacitor is suppressed and the gap between capacitors and the gap between electrodes can be filled while suppressing generation of voids. The method for manufacturing a semiconductor device comprises the steps of (a) preparing a substrate having semiconductor elements formed on a semiconductor substrate and having an oxide dielectric capacitor formed above the semiconductor substrate; (b) depositing a silicon oxide film by high density plasma (HDP) CVD under first conditions, the silicon oxide film covering the oxide dielectric capacitor; and (c) following the step (b), depositing a silicon oxide film by HDPCVD under second conditions wherein a high frequency bias is increased as compared with the first conditions.

### CROSS REFERENCE TO RELATED APPLICATION

This application is a continuation application of international application PCT/JP2004/010646 filed on Jul. 27, 2004, the entire contents of which are incorporated herein by reference.

### BACKGROUND OF THE INVENTION

A) Field of the Invention

The present invention relates to a semiconductor device and its manufacture method, and more particularly to a semiconductor device having oxide dielectric capacitors and its manufacture method.

B) Description of the Related Art

In a dynamic random access memory (DRAM), one memory cell is constituted of one transistor and one capacitor. In order to realize a desired capacitance by using a capacitor of a small size, a dielectric constant of a dielectric film of the capacitor is preferably made as high as possible. If the dielectric film is made of ferroelectric substance, polarization characteristics can be memorized and a non-volatile ferroelectric random access memory (FeRAM) can be realized.

Oxide having a perovskite structure such as barium strontium titanate (BST) BaSrTiO is known as high dielectric constant substance having a dielectric constant of 10 or higher or more preferably 50 or higher. Oxide having the perovskite structure such as PbZrTiO (PZT) and SrBiTiO (SBT) is known as ferroelectric substance. These oxide dielectric substance films of the perovskite structure can be formed by spin-on such as a sol-gel method, sputtering or chemical vapor deposition (CVD). In the following description, although a ferroelectric capacitor made of perovskite oxide ferroelectric substance will be used by way of example, this does not have limitative meaning.

A film of perovskite oxide ferroelectric substance has often an amorphous phase or insufficient crystallization, in the state of a film just after formation. Oxygen becomes poor in some cases. In these cases, oxide ferroelectric substance in the state of a film just after formation cannot be used as useful oxide ferroelectric substance. It is therefore necessary to perform annealing in an oxidizing atmosphere after the film is formed. Annealing in the oxidizing atmosphere may adversely affect the underlying structure such as transistors and W plugs.

Even if oxygen is supplemented and crystallization is performed, the characteristics of oxide ferroelectric substance are often degraded if the substance is exposed in a reducing atmosphere such as hydrogen at high temperature. After a ferroelectric capacitor is formed, the surface of the capacitor is covered with an insulating film such as an oxide film. If a silicon oxide film is formed at high temperature using gas which contains a large amount of hydrogen, hydrogen often deteriorates the characteristics of ferroelectric substance.

U.S. Pat. No. 5,953,619 (corresponding to JP-A-HEI-11-54716) teaches that after a switching MOS transistor is formed on a silicon substrate, an interlayer insulating film of borophosphosilicate glass (BPSG) or the like is formed on the substrate, covering the insulated gate electrode, contact holes are formed through the interlayer insulating film, conductive plugs are formed by burying the contact holes with conductive layer(s) such as Ti/TiN/W, a silicon nitride film and a silicon oxide film are formed thereon, and then ferroelectric capacitors are formed thereon. Even if annealing in an oxidizing atmosphere is performed, the silicon nitride film functions as an oxygen shielding film to protect the underlying structure from the oxidizing atmosphere. The silicon oxide functions as an adhesion layer. After the ferroelectric capacitors are formed, a silicon oxide film is formed by plasma enhanced (PE) chemical vapor deposition (CVD) using tetraethoxysilane (TEOS) as silicon source, to thereby form an interlayer insulating film burying the gap between the capacitors. Thereafter, Al wirings are formed connecting the capacitors and transistors. Using the TEOS oxide film suppresses generation of hydrogen and deterioration of the characteristics of the ferroelectric capacitor.

High integration of recent semiconductor devices results in high integration of ferroelectric capacitors, and gaps between ferroelectric capacitors and gaps between electrodes are narrowed. If a TEOS oxide film is used in a multi-layer wiring structure of a wiring rule of 0.35 μm or in the structure using a wiring rule of 0.18 μm or narrower, gap filling for a narrow gap with the silicon oxide film becomes insufficient and voids are formed.

### SUMMARY OF THE INVENTION

An object of the present invention is to provide a semiconductor device in which gaps between oxide dielectric capacitors and gaps between electrodes are filled with a silicon oxide film without forming voids and deterioration of capacitor characteristics is suppressed.

Another object of the present invention is to provide a method for manufacturing a semiconductor device capable of suppressing deterioration of the characteristics of oxide dielectric capacitors and filling gaps between capacitors and gaps between electrodes with an silicon oxide film while suppressing generation of voids.

Still another object of the present invention is to provide a highly integrated semiconductor device having ferroelectric capacitors with excellent characteristics.

Another object of the present invention is to provide a method for manufacturing a semiconductor device capable of forming ferroelectric capacitors with excellent characteristics at high integration and burying gaps between capacitors without forming voids.

According to one aspect of the present invention, there is provided a method for manufacturing a semiconductor device comprising the steps of: (a) preparing a semiconductor substrate formed with semiconductor elements and having an oxide dielectric capacitor formed above the semiconductor substrate; (b) depositing a silicon oxide film by high density plasma (HDP) CVD under first conditions, the silicon oxide film covering the oxide dielectric capacitor; and (c) following the step (b), depositing a silicon oxide film by HDPCVD under second conditions where a high frequency bias is increased as compared with the first conditions.

According to another aspect of the present invention, there is provided a semiconductor device comprising: a semiconductor substrate; semiconductor elements formed on the semiconductor substrate; an interlayer insulating film formed on the semiconductor substrate and covering the semiconductor elements; an oxide dielectric capacitor formed on the interlayer insulating film; a first silicon oxide film rich in silicon deposited on the interlayer insulating film and covering the oxide dielectric capacitor; and a second silicon oxide film deposited above the first silicon oxide film and having a smaller Si composition than a Si composition of the first silicon oxide film.

### BRIEF DESCRIPTION OF THE DRAWINGS

FIG. 1A is an equivalent circuit diagram of a ferroelectric random access memory (FeRAM), and FIG. 1B is a plan view showing a plan layout of an FeRAM.

FIG. 2 is a cross sectional view of a high density plasma (HDP) chemical vapor deposition (CVD) system used in the embodiment.

FIG. 3A is a schematic cross sectional view showing the structure of a sample used for experiments, and FIG. 3B is a graph showing the experimental results.

FIGS. 4A to 4H are cross sectional views illustrating main processes of a method for manufacturing a semiconductor device having ferroelectric capacitors according to an embodiment.

FIG. 5 is a cross sectional view showing an example of the structure of a ferroelectric capacitor and multi-layer wirings of a semiconductor device.

### DESCRIPTION OF THE PREFERRED EMBODIMENTS

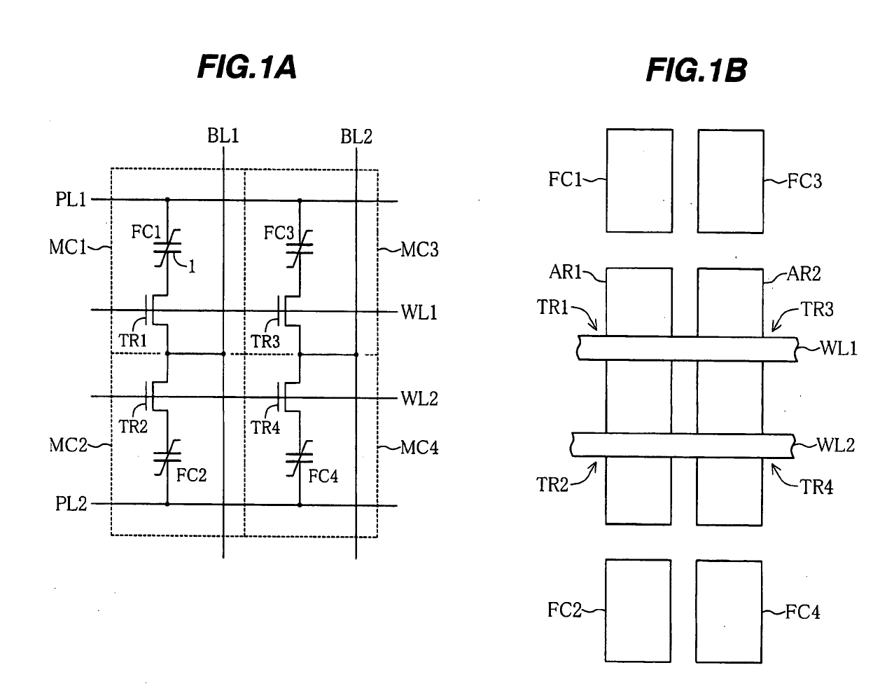

FIG. 1A shows an example of a circuit configuration of an FeRAM. Four memory cells are shown in FIG. 1A. A MOS transistor TR1 and a ferroelectric capacitor FC1 of ferroelectric substance constitute one memory cell MC1. Similarly, a MOS transistor TR2 and a ferroelectric capacitor FC2 constitute one memory cell MC2, a MOS transistor TR3 and a ferroelectric capacitor FC3 constitute one memory cell MC3, and a MOS transistor TR4 and a ferroelectric capacitor FC4 constitute one memory cell MC4. Source regions of two vertically juxtaposed transistors are constituted of a common semiconductor region and connected to a bit line BL1 or BL2. Gate electrodes of horizontally juxtaposed MOS transistors are connected to a common word line WL1 or WL2. Opposing electrodes of the capacitors are connected to a plate line PL1 or PL2. If a paraelectric capacitor is used in place of the ferroelectric capacitor, a DRAM is formed.

One memory cell may be constituted of one transistor and one capacitor, or two transistors connected to the same word line and two capacitors connected to the transistors. BL and /BL are used for the bit lines BL1 and BL2 to store complementary data and double a signal margin.

FIG. 1B shows an example of a plan layout of a semiconductor device realizing the circuit shown in FIG. 1A. Semiconductor active regions AR1 and AR2 and gate electrodes (portions of the word lines WL1 and WL2) disposed above the active regions constitute four transistors TR1 to TR4. Four ferroelectric capacitors FC1 to FC4 are disposed below and above the transistors. Ferroelectric capacitors FC1 and FC3 are disposed horizontally juxtaposed, and ferroelectric capacitors FC2 and FC4 are also disposed horizontally juxtaposed. As the integration degree becomes high, the gap between capacitors becomes narrow, e.g., about 0.35 μm or 0.18 μm.

In order to bury a narrow gap with an insulating film such as silicon oxide, it is necessary to adopt a film forming method having good gap filling capacity. A method of forming a silicon oxide film having excellent gap filling capacity is high density plasma (HDP) CVD. Silane (SiH₄), O₂ and Ar are generally used as source gases for an HDP silicon oxide film. As silane is decomposed, a large amount of hydrogen is generated. If a silicon oxide film covering the ferroelectric capacitor is formed by HDPCVD, the characteristics of the ferroelectric capacitor will be deteriorated. There is a tradeoff between the gap filling capacity and the characteristics of a ferroelectric capacitor.

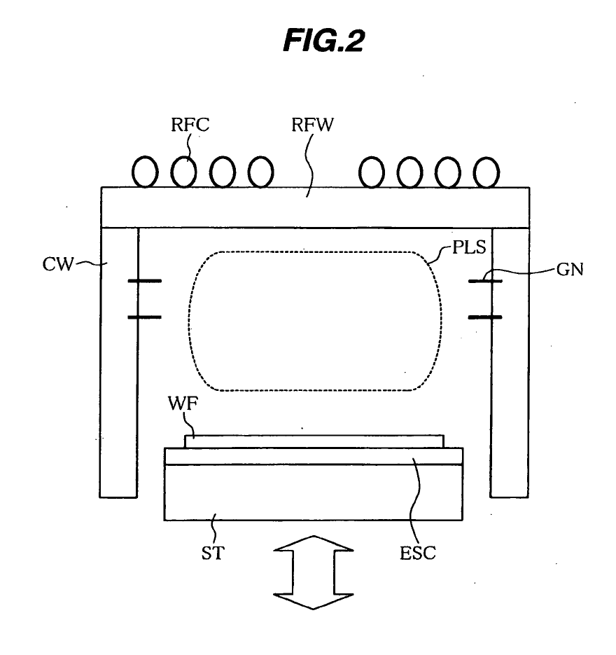

FIG. 2 shows the structure of an inductively coupled HDPCVD system having excellent gap filling. An RF window RFW made of alumina and transmitting radio frequency (RF) is disposed at an upper plane of a chamber wall CW made of aluminum. A coil RFC of several turns is disposed on the RF window to supply a high frequency power at 13.56 MHz. A plurality of gas nozzles GN are equipped through the chamber wall CW to supply desired gases and form a mixture gas atmosphere. An electrostatic chuck ESC is formed on a stage ST capable of moving up and down. A high frequency bias at a frequency of 4 MHz and a bias power of 2.0 kw to 3.0 kw is applied to the stage ST. The space in the chamber is connected to an evacuation system and can be maintained at a desired vacuum degree. For example, by supplying SiH₄, O₂ and Ar at predetermined flow rates and applying an RF power and a high frequency bias, high density plasma PLS can be generated under the RF window RFW and a silicon oxide film can be deposited on a wafer WF. HDPCVD is a process which progresses deposition and sputtering at the same time. It is said that gap filling can be improved because sputtering progresses preferentially at a convex portion.

The present inventor has considered to turn off the high frequency bias in order to mitigate the influence of hydrogen. When a silicon oxide film is formed by HDPCVD without the high frequency bias, the gap filling function will be degraded. To avoid this, a silicon oxide film having a different physical property is deposited at the initial stage without the high frequency bias, thereafter by turning on a high frequency bias, a silicon film having excellent gap filling is deposited. If the lower silicon oxide film presents a hydrogen shielding function, it will be possible to suppress deterioration of the characteristics of a ferroelectric capacitor. By forming the upper silicon oxide film by general HDPCVD, the gap filling performance will be retained.

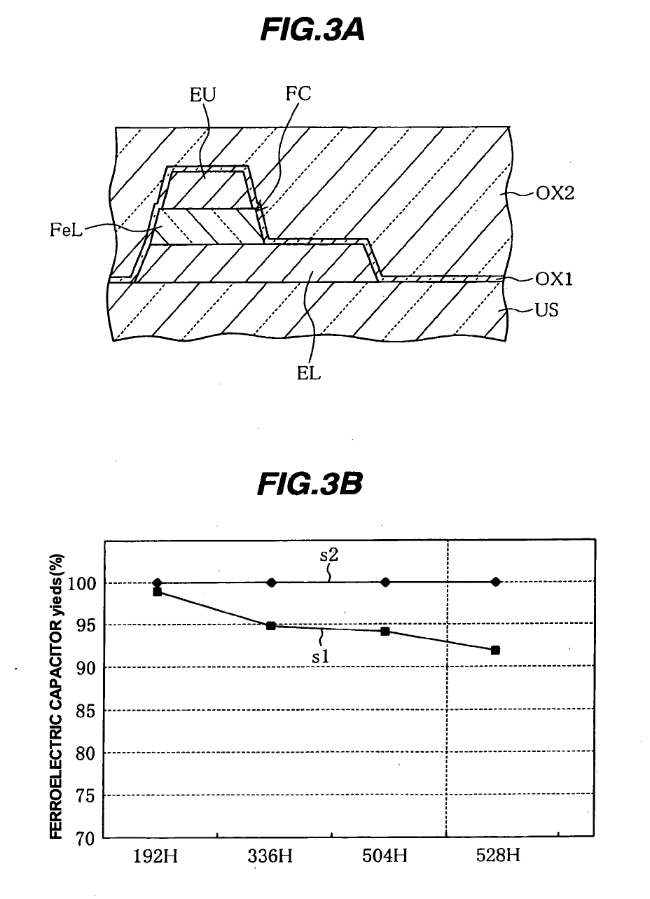

FIG. 3A shows the structure of a sample. On an underlying layer US on a silicon substrate, a lower electrode EL of noble metal, a PZT ferroelectric layer FeL and an upper electrode EU of noble metal are formed to form a ferroelectric capacitor FC. A lower silicon oxide film OX1 was deposited covering the ferroelectric capacitor FC, by HDPCVD using SiH₄, O₂ and Ar as source gases and turning off the high frequency bias. Thereafter, by turning on the high frequency bias, an upper silicon oxide film OX2 was deposited. Yields of ferroelectric capacitor characteristics were measured by changing thicknesses of the lower silicon oxide film OX1.

FIG. 3B is a graph showing experimental results. Characteristics s1 indicate an experimental result at a thickness of 9 nm of the lower silicon oxide film OX1. A yield at a lapse of 192 hours after manufacture is near 100%, the yield lowers as the time lapses, and the yield lowers to about 92% at a lapse of 528 hours after the manufacture. Characteristics s2 indicate an experimental result at a thickness of 12.7 nm of the lower silicon oxide film OX1. A yield is almost 100% at a lapse of 528 hours after manufacture. Good results were obtained also at thicknesses of 18.5 nm, 39 nm and 49.5 nm.

It has been found from these experimental results that damages are formed if a silicon oxide film covering the ferroelectric capacitor is formed by HDPCVD applying the high frequency bias, damages are reduced if a silicon oxide film is formed by turning off the high frequency bias in the initial film forming stage, and the yield is maintained at nearly 100% if the lower silicon oxide film having a thickness of 10 nm or thicker is formed without the high frequency bias. Silicon oxide formed by HDPCVD without the high frequency bias was rich in Si. Silicon oxide rich in Si formed by HDPCVD without the high frequency bias is considered as having a diffusion preventive function for hydrogen and moisture (hereinafter also called hydrogen shielding function).

The diffusion preventive function for hydrogen and moisture becomes higher the thicker the lower silicon oxide film formed by HDPCVD without the high frequency bias is. However, the gap filling function is degraded. It is not preferable to form too thick the lower silicon oxide film by HDPCVD without the high frequency bias, and the thickness is preferably set to 50 nm or thinner. In order to retain the diffusion preventive function for hydrogen and moisture, the thickness is preferably 10 nm or thicker. Namely, it is preferable to form the lower silicon oxide film having a thickness of 10 nm to 50 nm without the high frequency bias. A substrate temperature during HDPCVD is preferably 175° C. to 350° C.

A SiON film may be formed by using SiH₄, N₂O and Ar as source gases instead of SiH₄, O₂ and Ar. F may be added to silicon oxide to lower a dielectric constant. A low dielectric constant film may be formed by HDPCVD using SiF₄/O₂/Ar.

The hydrogen diffusion preventive function can be improved if an insulating film having the hydrogen diffusion preventive function such as an Al oxide film, an Al nitride film, a Ta oxide film, a Ta nitride film, a Ti oxide film and a Zr oxide film is formed before forming the silicon oxide film by HDPCVD without the high frequency bias. A dehydration process and film quality improvement can be realized by executing a plasma process using N₂ or N₂O after the silicon oxide film is formed by HDPCVD lowering the high frequency bias or after the silicon oxide films are formed by HDPCVD lowering the high frequency bias and by HDPCVD increasing the high frequency bias. In this case, the substrate temperature is preferably 200° C. to 450° C. After gaps are filled, a silicon oxide film may be formed by plasma CVD using TEOS. A plasma process using N₂ or N₂O is effective after an oxide film is formed by plasma CVD using TEOS. An amount of hydrogen generation can be suppressed. Thereafter, planarization may be performed by chemical mechanical polishing. A ratio between deposition and sputtering of HDPCVD may be changed by controlling a ratio of a flow rate of Ar, 02 gases to a flow rate of silicon source gas of SiH₄.

Although the initial film growth is performed without the high frequency bias, similar advantages are expected also by lowering the high frequency bias in the initial film growth stage. The high frequency bias may be lowered first and then gradually increased.

If the total thickness of silicon oxide films become thick as in the case of multi-layer wirings, silicon oxide films formed without the high frequency bias and silicon oxide films formed with the high frequency bias may be laminated at a desired ratio. Namely, a plurality of silicon oxide films formed without the high frequency bias may be inserted into the total thickness of silicon oxide films.

It is effective to form silicon oxide films without the high frequency bias at an increased total flow rate than that for forming silicon oxide films with the high frequency bias. It is also effective to form a silicon oxide film without the high frequency bias at an increased ratio of a silane flow rate to the total flow rate. For example, a flow rate of silane SiH₄ is set to five times the flow rate of O₂.

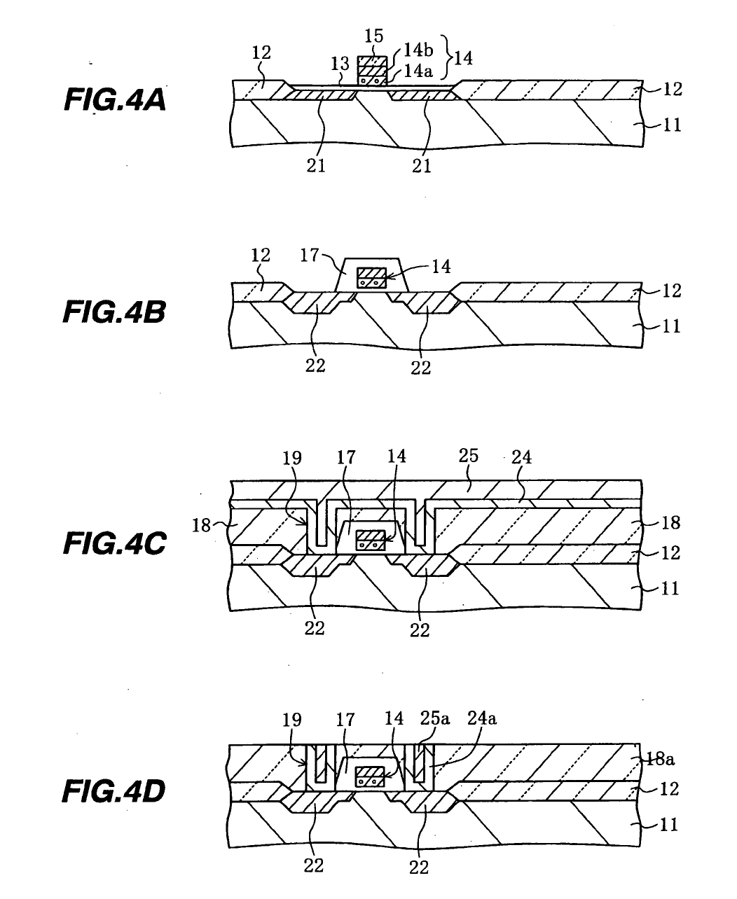

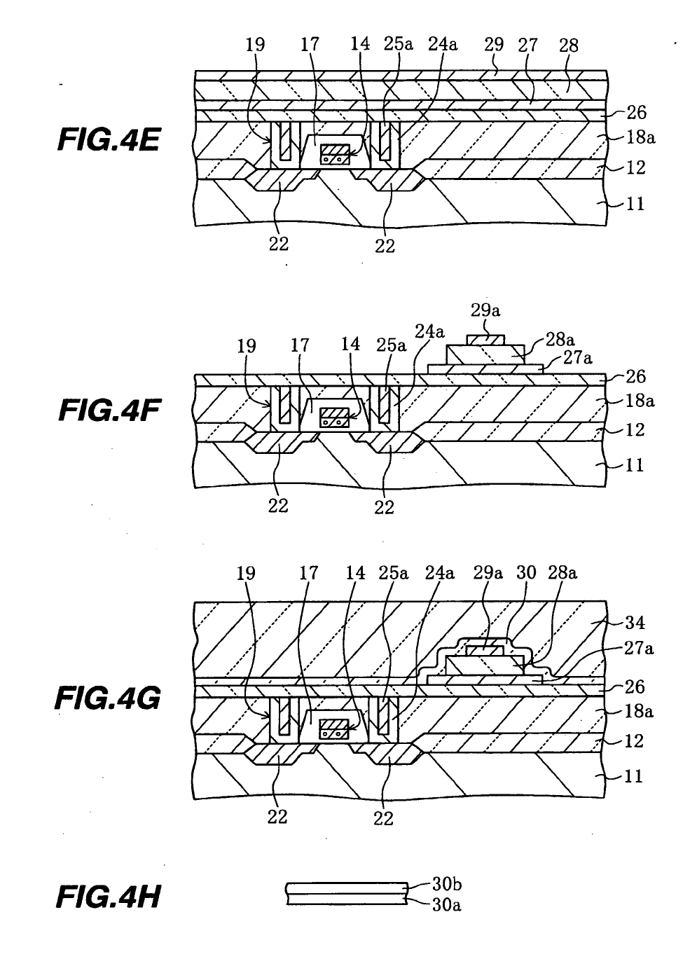

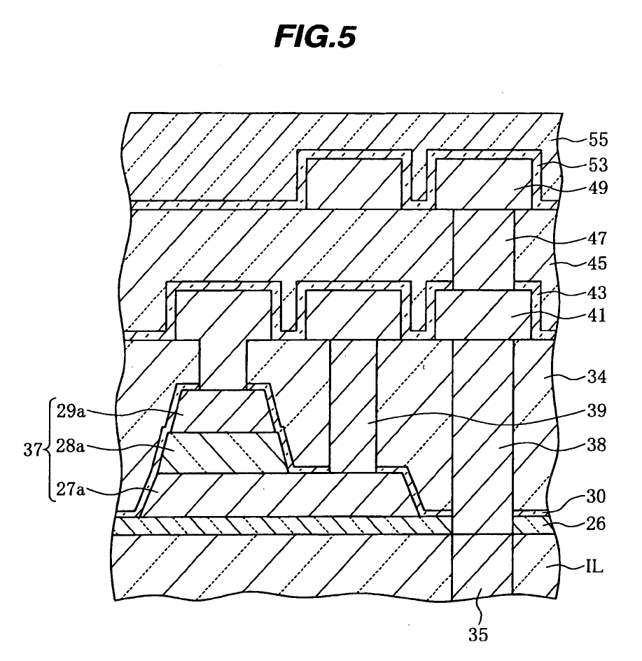

With reference to FIGS. 4A to 4H, description will be made on main processes of a manufacture method for a semiconductor device according to an embodiment of the present invention.

As shown in FIG. 4A, a field oxide film 12 having a thickness of about 500 nm is formed on the surface of a p-type silicon substrate 11 by local oxidation of silicon (LOCOS). Although the silicon substrate 11 of the p-type is illustratively used, an n-type well, a p-type well and a p-type well in the n-type well may be formed in the surface layer of the silicon substrate 11. All conductivity types may be reversed. The isolation region may be formed by shallow trench isolation (STI) instead of LOCOS.

A gate oxide film 13 having a thickness of about 15 nm is formed by thermal oxidation on the surface of the silicon substrate 11 (active region AR) defined by the field oxide film 12. A gate electrode layer 14 is formed by depositing a polysilicon layer 14a having a thickness of about 120 nm and a tungsten silicide (WSi) layer 14b having a thickness of about 150 nm on the gate oxide film 13. The gate electrode layer can be formed by sputtering, CVD or the like. A silicon oxide film 15 is formed on the gate electrode layer 14 by CVD. A resist pattern is formed on the silicon oxide film 15, and the silicon oxide film 15 and gate electrode layer 14 are patterned in the same shape. The resist mask is thereafter removed.

By using the pattern of the gate electrode layer 14 and silicon oxide film 15 as a mask, n-type impurity ions are implanted at a low impurity concentration into the surface layer of the silicon substrate 11 to form low concentration n-type impurity doped regions (extensions) 21. If a CMOS circuit is to be formed on the silicon substrate, ion implantation is performed separately for n-channel regions and p-channel regions.

For example, P and/or As ions are implanted for n-channel transistors, and BF₂ ions are implanted for p-channel transistors. A dose is about 10¹³ cm⁻², for example.

As shown in FIG. 4B, a high temperature oxide (HTO) film covering the gate electrode structure is deposited on the whole surface of the silicon substrate 11, at a substrate temperature of 800° C. and to a thickness of about 150 nm. Thereafter, reactive ion etching (anisotropic etching) is performed to remove the HTO film on the flat surface and leave sidewall spacers only on the side walls of the gate electrode structure. The silicon oxide film 15 formed previously is left on the upper surface of the gate electrode. The silicon oxide film 15 and side wall spacers are collectively called a first insulating film 17 hereinafter.

By using the first insulating film 17 as a mask, ion implantation is performed at a high impurity concentration to form deeper source/drain regions 22 having a high impurity concentration. For example, As ions are implanted at a dose of about 10¹⁴ to 10¹⁵ cm⁻² for n-channel transistors, and BF₂ ions are implanted at a dose of about 10¹⁴ to 10¹⁵ cm⁻² for p-channel transistors.

As shown in FIG. 4C, an oxide film 18 of borophosphosilicate glass (BPSG), oxynitride, silicon oxide or the like is formed on the whole surface of the silicon substrate 11. After the oxide film 18 is formed, the surface thereof is planarized to set the thickness to about 1 μm.

The oxide film 18 may be made of a single layer or a lamination of a plurality of layers. For example, an oxynitride layer having a thickness of about 200 nm is formed and a plasma enhanced tetraethoxysilane (TEOS) oxide film is formed on the oxynitride layer. Planarizing the oxide film 18 can be performed by reflow, chemical mechanical polishing (CMP), etch-back or the like.

After the surface of the oxide film 18 is planarized, contact holes 19 are formed exposing the source/drain regions of the MOS transistor. The contact holes 19 can be formed by reactive ion etching, using a resist mask having openings with a diameter of about 0.5 μm for example.

A wiring layer is formed on the substrate formed with the contact holes 19. For example, the wiring layer is made of a glue metal layer 24 and a W layer 25 deposited on the glue metal layer. The glue metal layer is made of a lamination of a Ti layer having a thickness of about 20 nm and a TiN layer having a thickness of about 50 nm. The glue metal layer is deposited, for example, by sputtering. The W layer is deposited to a thickness of about 800 nm by CVD using WF₆ and H₂. The contact holes 19 are buried by the wiring layer to form the wiring layer connected to the source/drain regions 22.

As shown in FIG. 4D, the W layer 25 and glue metal layer 24 on the oxide film 18 are removed by etch-back. The etch-back can be performed by dry etching using Cl-containing gas. The W layer and glue metal layer on the oxide film 18 may be removed by chemical mechanical polishing (CMP). With this etch-back or CMP, the oxide film 18a, and metal plugs of the glue metal layer 24a and W layer 25a form generally the flat surface. The surface of the W layer 25a may become lower than the peripheral surface when etch-back is done.

As shown in FIG. 4E, a nitride film 26 having a thickness of about 50 nm to 100 nm is deposited on the planarized surface by plasma enhanced (PE) CVD at a low substrate temperature of about 350° C. The reason of forming the nitride film at a low temperature is to prevent oxidation of the W layer 25a and to prevent silicidation of the Ti layer contacting the silicon substrate, which may break the junction.

After the nitride film is formed, it is preferable to form an oxide film having a thickness of about 80 nm. For example, this oxide film may be a TEOS oxide film formed by plasma enhanced CVD using TEOS. By limiting the substrate temperature, junction breakage by silicification can be prevented.

The nitride film covers the metal plugs buried in the contact holes, and prevents oxidation of the metal plugs to be caused by oxygen entering from the surface at later processes.

If the oxide film is formed on the nitride film, adhesion to the capacitor lower electrode formed on the oxide film can be improved. In the following, the layer 26, including the single nitride film and a lamination of the nitride film and oxide film, is called an oxygen shielding insulating film.

On the oxygen shielding insulating film 26, a lower electrode 27, a PZT dielectric film 28 having a thickness of 300 nm and a Pt upper electrode 29 having a thickness of 150 nm are formed by sputtering. The lower electrode 27 is made of a lamination of a Ti layer having a thickness of 20 to 30 nm and a Pt layer having a thickness of 150 nm. The PZT dielectric film 28 in a deposited state has an amorphous phase and does not have the polarization characteristics.

After the PZT dielectric film 28 is formed and before the upper electrode 29 is deposited or after the upper electrode 29 is deposited, an annealing process is executed in an ° 2 atmosphere. For example, the annealing process is executed for about 5 seconds at 850° C. in an atmosphere of O₂ at 1 atm. This annealing process can be executed by using a rapid thermal annealing (RTA) system. Instead of RTA, a resistance heating furnace may be used to execute the annealing process for 10 minutes or longer at 800° C. or higher, e.g., for about 30 minutes at 800° C.

With the annealing process in the oxygen atmosphere, the PZT dielectric film 28 is polycrystallized and presents a polarizability of, e.g., about 30 μC/cm². The W layer 25a is protected from oxidation because it is covered with the oxygen shielding insulating film 26. If the W layer 25a is oxidized, there is a risk of breaking the lamination structure due to volume expansion. For example, the W layer may expand by 1 μm in the height direction.

As shown in FIG. 4F, the upper electrode 29, dielectric film 28 and lower electrode 27 are patterned by well-known photolithography techniques. This patterning forms a lower electrode 27a, a dielectric film 28a and an upper electrode 29a. In order to make steps gentle, it is preferable to reduce the areas gradually from the lower layer toward the upper layer. After capacitor patterning, a recovery annealing process is executed in an oxygen atmosphere at a temperature of 500 to 650° C.

The PZT dielectric film 28a presents excellent polarization characteristics when it presents (111) orientation on the lower electrode. In order to realize this crystalline orientation, it is preferable to control a Ti thickness of the lower electrode 27a and to set a Pb composition x in the PZT dielectric film 28a to 1 to 1.4 or more preferably about 1.1, where the PZT composition other than oxygen is represented by PbₓZr_{y}Ti_{1-y}. After the PZT dielectric film is formed, it is preferable to avoid a high temperature process using reducing gas such as hydrogen, as much as possible.

As shown in FIG. 4G, a first silicon oxide film 30 which is rich in Si and has a thickness of 10 nm to 50 nm is formed on the whole surface of the substrate, by HDPCVD without the high frequency bias described earlier. A hydrogen (moisture) diffusion preventive film 30 is therefore formed. Thereafter, a second silicon oxide film 34 with a reduced Si composition (nearly stoichiometry) is formed to a desired thickness by HDPCVD with the high frequency bias excellent in gap filling function. CMP is performed to planarize the surface.

As shown in FIG. 4H, the hydrogen diffusion preventive film may be a lamination of, e.g., a first hydrogen diffusion preventive film 30a and a second hydrogen diffusion preventive film 30b. One of the films is a silicon oxide rich in Si, and the other is a film made of one of Al oxide, Al nitride, Ta oxide, Ta nitride, Ti oxide and Zr oxide. Thereafter, multi-layer wirings are formed as necessary. For the general structure and manufacture processes of a ferroelectric memory, reference may be made to U.S. Pat. No. 5,953,619 (corresponding to JP-A-HEI-11-54716), the contents of which are incorporated herein by reference.

FIG. 5 shows an example of the structure of a ferroelectric capacitor and multi-layer wirings formed over the capacitor. A conductive plug 35 is buried in an interlayer insulating film IL. An oxygen shielding insulating film 26 is formed on the interlayer insulating film. On the oxygen shielding insulating film 26, a ferroelectric capacitor 37 is formed which is constituted of a lower electrode 27a, a ferroelectric layer 28a and an upper electrode 29a. A silicon oxide film 30 is formed covering the ferroelectric capacitor and a silicon oxide film 34 is deposited on the silicon oxide film 30 to constitute an interlayer insulating film. The silicon oxide film 30 is formed by HDPCVD without the high frequency bias, is rich in Si and has a hydrogen shielding function, whereas the silicon oxide film 34 is formed by HDPCVD with the high frequency bias, is excellent in gap filling function and nearly stoichiometric although it lacks the hydrogen shielding function.

In the structure shown in FIG. 5, via holes are formed reaching the conductive plug 35 and lower electrode 27a, and conductive plugs 38 and 39 of such as W are buried by the process described earlier. After a via hole is formed reaching the upper electrode 29a, an Al layer is deposited and patterned to form first Al wirings 41. Here, it is possible to form a conductive plug also on the upper electrode 29a. A silicon oxide film 43, which is rich in Si, has a hydrogen shielding function and covers the first Al wirings 41, is formed on the silicon oxide film 34, by HDPCVD without the high frequency bias. Next, a silicon oxide film 45 is deposited by HDPCVD with the high frequency bias, the silicon oxide film 45 being excellent in gap filling although it lacks the hydrogen shielding function. A via hole reaching the underlying contact area is formed through the silicon oxide films 45 and 43 and a conductive plug 47 is buried in the via hole. An Al layer is deposited and patterned to form second Al wirings 49.

Similarly, a silicon oxide film 53 having the hydrogen shielding function is formed covering the second Al wirings 49, and a silicon oxide film 55 is deposited which is excellent in gap filling function, although it lacks the hydrogen shielding function. With similar processes, a desired number of multi-layer wirings are formed.

The present invention is applicable to general semiconductor memory devices.

The present invention has been described in connection with the preferred embodiments. The invention is not limited only to the above embodiments. For example, which one of the lower and upper electrodes of a ferroelectric capacitor is connected to the plate line or transistor is optional. Instead of an Al wiring, a Cu damascene wiring may be formed. Instead of PZT, other materials such as SBT may also be used. High dielectric constant material such as BST may be used in place of ferroelectric substance. An electrode having an oxygen shielding function may be formed on the surface of the lower level conductive plug to omit the oxygen shielding film. It will be apparent to those skilled in the art that other various modifications, improvements, combinations, and the like can be made.

What I claim are:

1. A method for manufacturing a semiconductor device comprising the steps of:
(a) preparing a substrate formed with semiconductor elements on a semiconductor substrate and having an oxide dielectric capacitor formed above said semiconductor substrate;
(b) depositing a silicon oxide film by high density plasma (HDP) CVD under first conditions, the silicon oxide film covering said oxide dielectric capacitor; and
(c) following said step (b), depositing a silicon oxide film by HDPCVD under second conditions wherein a high frequency bias is increased as compared with said first conditions.

2. The method for manufacturing a semiconductor device according to claim 1, wherein said first conditions in said step (b) form a silicon oxide film having a hydrogen shielding function, without using a high frequency bias.

3. The method for manufacturing a semiconductor device according to claim 1, wherein a high frequency bias is gradually increased from said first conditions toward said second conditions.

4. The method for manufacturing a semiconductor device according to claim 1, wherein a thickness of said silicon oxide film formed in said step (b) is 10 nm to 50 nm.

5. The method for manufacturing a semiconductor device according to claim 1, wherein in said steps (b) and (c), a substrate temperature is 175° C. to 350° C.

6. The method for manufacturing a semiconductor device according to claim 1, wherein said steps (b) and (c) use mixture gas of SiH₄, O₂ and Ar, mixture gas of SiH₄, N₂, O and Ar or mixture gas of SiF₄, O₂ and Ar as source gas.

7. The method for manufacturing a semiconductor device according to claim 1, wherein in said steps (b) and (c), a ratio between deposition and sputtering is changed by changing a ratio of a flow rate of silicon source gas to a flow rate of other source gases.

8. The method for manufacturing a semiconductor device according to claim 1, further comprising the step of:
(d) executing a plasma process using N₂ or N₂O after said step (b) or after said steps (b) and (c) to realize a dehydration process and film quality improvement.

9. The method for manufacturing a semiconductor device according to claim 1, further comprising the step of:
(e) depositing a layer made of Al oxide, Al nitride, Ta oxide, Ta nitride, Ti oxide or Zr oxide, covering said oxide dielectric capacitor.

10. A semiconductor device comprising:
a semiconductor substrate;
semiconductor elements formed on said semiconductor substrate;
an interlayer insulating film formed on said semiconductor substrate and covering said semiconductor elements;
an oxide dielectric capacitor formed on said interlayer insulating film;
a first silicon oxide film rich in silicon deposited on said interlayer insulating film and covering said oxide dielectric capacitor; and
a second silicon oxide film deposited above said first silicon oxide film and having a smaller Si composition than a Si composition of said first silicon oxide film.

11. The semiconductor device according to claim 10, wherein oxide dielectric substance of said oxide dielectric capacitor is PZT, SBT or BST.

12. The semiconductor device according to claim 10, wherein a thickness of said first silicon oxide film is 10 nm to 50 nm.
